(19) United States
(12) Patent Application Publication
(10) Pub. No.: US 2018/0286899 A1
(43) Pub. Date: Oct. 4, 2018

(54) METHOD OF MANUFACTURING OPTICAL SEMICONDUCTOR DEVICE

(71) Applicant: HAMAMATSU PHOTONICS K.K., Hamamatsu-shi (JP)

(72) Inventors: Masaharu MURAMATSU, Hamamatsu-shi (JP); Yasuhito MIYAZAKI, Hamamatsu-shi (JP); Hirotaka TAKAHASHI, Hamamatsu-shi (JP)

(73) Assignee: HAMAMATSU PHOTONICS K.K., Hamamatsu-shi (JP)

(21) Appl. No.: 15/942,759

(22) Filed: Apr. 2, 2018

(30) Foreign Application Priority Data
Apr. 4, 2017 (JP) 2017-074499

(51) Int. Cl. H01L 27/146

(52) U.S. Cl. CPC H01L 27/1463; H01L 21/3065; H01L 27/14685; H01L 27/14623

(57) ABSTRACT

A method of manufacturing an optical semiconductor device includes preparing a semiconductor substrate having a plurality of photoelectric conversion parts, forming a trench in the semiconductor substrate to separate the plurality of photoelectric conversion parts from each other, forming a boron layer on an inner surface of the trench by a vapor phase growth method, and forming an accumulation layer in the semiconductor substrate along the inner surface of the trench by performing a thermal diffusion treatment on the boron layer.

### TECHNICAL FIELD

The present disclosure relates to a method of manufacturing an optical semiconductor device.

### BACKGROUND

An optical semiconductor device which includes a semiconductor substrate having a plurality of photoelectric conversion parts and in which trenches are formed in the semiconductor substrate to separate the respective photoelectric conversion parts from each other is known (for example, Japanese Unexamined Patent Publication No. 2003-86827).

### SUMMARY

In the above-described optical semiconductor device, preferably a deep trench of which an opening has a narrow width is formed to more reliably suppress generation of crosstalk between mutually adjacent photoelectric conversion parts while maintaining a narrow interval between adjacent photoelectric conversion parts. However, when a defect occurs in the semiconductor substrate along an inner surface of the trench during formation of such a trench, the defect may cause a dark current to be generated. An accumulation layer may be formed in the semiconductor substrate along the inner surface of the trench by ion implantation. However, in a deep trench of which an opening has a narrow width, it is difficult to form an accumulation layer at a deepest portion of the trench by ion implantation.

An object of the present disclosure is to provide a manufacturing method of an optical semiconductor device by which an accumulation layer is able to be reliably formed at a deepest portion of a trench even in a case of a deep trench of which an opening has a narrow width.

A method of manufacturing an optical semiconductor device according to one aspect of the present disclosure includes preparing a semiconductor substrate having a plurality of photoelectric conversion parts, forming a trench in the semiconductor substrate to separate the plurality of photoelectric conversion parts from each other, forming a boron layer on an inner surface of the trench by a vapor phase growth method, and forming an accumulation layer in the semiconductor substrate along the inner surface of the trench by performing a thermal diffusion treatment on the boron layer.

In the method of manufacturing the optical semiconductor device, the boron layer is formed on the inner surface of the trench by the vapor phase growth method. Therefore, even in a case of a trench which is deep and of which an opening has a narrow width, the boron layer is formed isotropically on the inner surface of the trench. Therefore, the accumulation layer formed by thermal diffusion on the boron layer is uniformly formed in the semiconductor substrate along the inner surface of the trench. Thus, according to the method of manufacturing the optical semiconductor device, even in the case of the trench of which an opening has the narrow and deep width, it is possible to reliably form the accumulation layer to a deepest portion of the trench.

In the method of manufacturing the optical semiconductor device according to one aspect, the trench may be formed in the semiconductor substrate by reactive ion etching in the forming of the trench. Therefore, it is possible to form the trench of which the opening has the narrow and deep width.

The method of manufacturing the optical semiconductor device according to one aspect may further include forming a light shielding layer in the trench after the forming of the accumulation layer. Therefore, in the manufactured optical semiconductor device, it is possible to more reliably suppress generation of crosstalk between photoelectric conversion parts adjacent to each other.

According to the present disclosure, it is possible to provide a manufacturing method of an optical semiconductor device capable of reliably forming an accumulation layer to a deepest portion of a trench even in a case of a trench of which an opening has a narrow and deep width.

### BRIEF DESCRIPTION OF THE DRAWINGS

FIG. 1 is a plan view of an optical semiconductor device according to one embodiment.

FIG. 2 is a cross-sectional view taken along line II-II illustrated in FIG. 1.

FIG. 3 is a cross-sectional view for explaining a method of manufacturing the optical semiconductor device illustrated in FIG. 1.

FIG. 4 is a cross-sectional view for explaining the method of manufacturing the optical semiconductor device illustrated in FIG. 1.

FIG. 5 is a cross-sectional view for explaining the method of manufacturing the optical semiconductor device illustrated in FIG. 1.

FIG. 6 is a cross-sectional view for explaining the method of manufacturing the optical semiconductor device illustrated in FIG. 1.

FIG. 7 is a cross-sectional view for explaining the method of manufacturing the optical semiconductor device illustrated in FIG. 1.

FIG. 8 is a cross-sectional view for explaining the method of manufacturing the optical semiconductor device illustrated in FIG. 1.

### DETAILED DESCRIPTION

Hereinafter, an embodiment of the present disclosure will be described in detail with reference to the drawings. In each of the drawings, the same or corresponding parts are designated by the same reference numerals, and duplication of parts may be omitted.

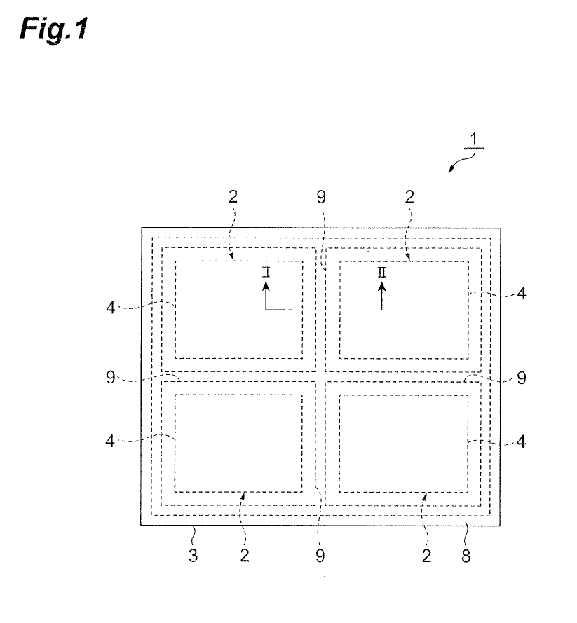

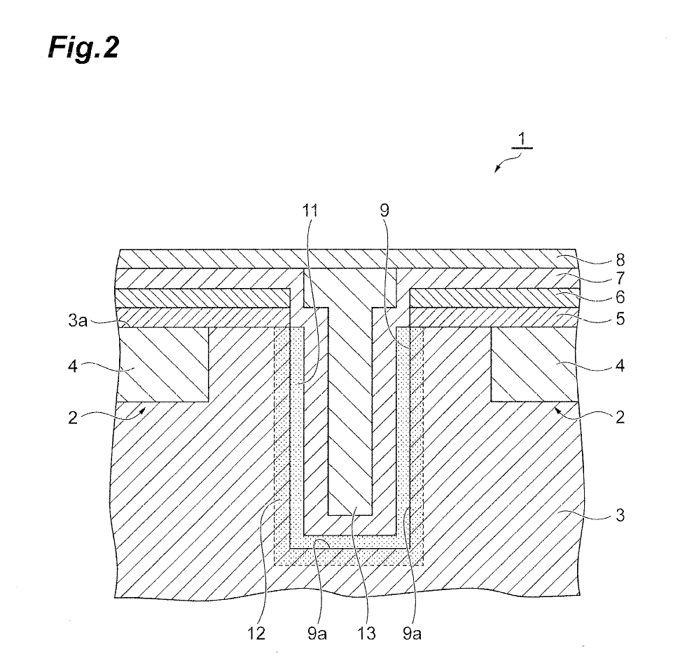

As illustrated in FIGS. 1 and 2, an optical semiconductor device 1 includes a semiconductor substrate 3 having a plurality of photoelectric conversion parts 2. The plurality of photoelectric conversion parts 2 are constituted by forming a plurality of semiconductor layers 4 in a matrix shape on a portion of the semiconductor substrate 3 along a surface 3a thereof. Each of the photoelectric conversion parts 2 constitutes a pixel. That is, the optical semiconductor device 1 is a solid-state imaging device. The semiconductor substrate 3 is, for example, a semiconductor substrate (first conductivity type semiconductor substrate) formed of p-type silicon. The semiconductor layer 4 is, for example, a semiconductor layer (second conductivity type semiconductor layer) to which an n-type impurity is added.

On the surface 3a of the semiconductor substrate 3, insulating layers 5, 6, 7 and 8 are stacked in turn to cover the plurality of semiconductor layers 4. The insulating layers 5, 7 and 8 are, for example, silicon oxide films. The insulating layer 6 is, for example, a silicon nitride film. For example, the insulating layers 5, 6 and 7 serve as gate insulating films or the like. For example, the insulating layer 8 serves as a protective film or the like. Wires or the like (not illustrated) are also formed on the surface 3a of the semiconductor substrate 3.

Trenches 9 are formed in the semiconductor substrate 3 to separate the photoelectric conversion parts 2 from each other. The trenches 9 open on the surface 3a of the semiconductor substrate 3. The trenches 9 are formed in a lattice shape to pass between adjacent photoelectric conversion parts 2 when seen in a direction perpendicular to the surface 3a of the semiconductor substrate 3. A width of an opening of each of the trenches 9 is, for example, about 0.5 μm, and a depth of each of the trenches 9 is, for example, about 10 μm.

A boron layer 11 is formed on an inner surface (specifically, a side surface and a bottom surface) 9a of the trench 9. The boron layer 11 is formed to continuously cover the entire inner surface 9a of the trench 9. An accumulation layer 12 is formed in a portion of the semiconductor substrate 3 along the inner surface 9a of the trench 9. The accumulation layer 12 is a layer in which a part of the boron layer 11 has diffused into a portion of the semiconductor substrate 3 along the inner surface 9a of the trench 9. Since the accumulation layer 12 is formed in a portion of the semiconductor substrate 3 along the inner surface 9a of the trench 9, generation of a dark current due to a defect occurring in the semiconductor substrate 3 along the inner surface 9a of the trench 9 is suppressed.

The insulating layer 7 extends from the surface 3a of the semiconductor substrate 3 into the trench 9 and covers the boron layer 11 in the trench 9. In the trench 9, a light shielding layer 13 is formed on the insulating layer 7. The light shielding layer 13 is covered with the insulating layer 8. The light shielding layer 13 is formed by filling the trench 9 with a light shielding material, such as, for example, tungsten or polysilicon with the insulating layer 7 therebetween. The light shielding layer 13 is electrically insulated from the boron layer 11 and the semiconductor substrate 3 because the insulating layer 7 is interposed between the boron layer 11 and the light shielding layer 13. Therefore, in the photoelectric conversion parts 2 adjacent to each other with the trench 9 interposed therebetween, it is possible to prevent electrical leakage from occurring through the light shielding layer 13. Since the trenches 9 are formed in the semiconductor substrate 3 and separate the photoelectric conversion parts 2 from each other and the light shielding layer 13 is also formed in the trenches 9, generation of crosstalk between the photoelectric conversion parts 2 adjacent to each other is more reliably suppressed. Further, a buffer layer for enhancing adhesion of the light shielding layer 13 may be provided between the insulating layer 7 and the light shielding layer 13. The buffer layer is formed by, for example, stacking TiN and Ti on the insulating layer 7 in this order.

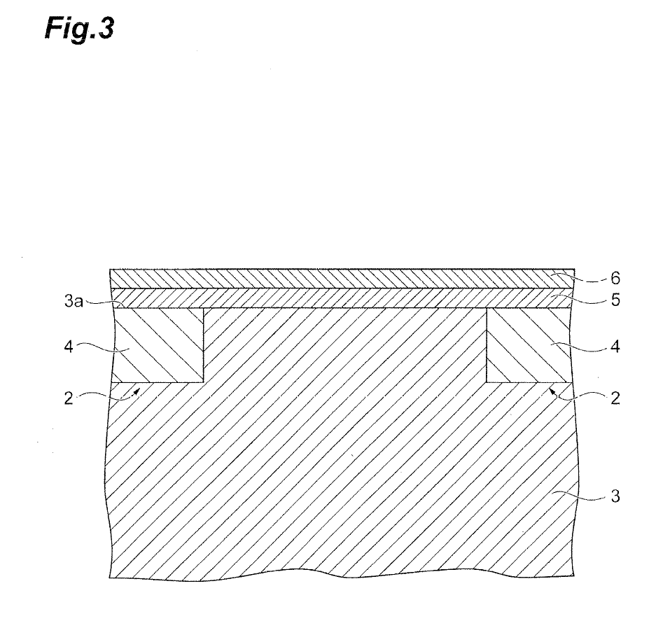

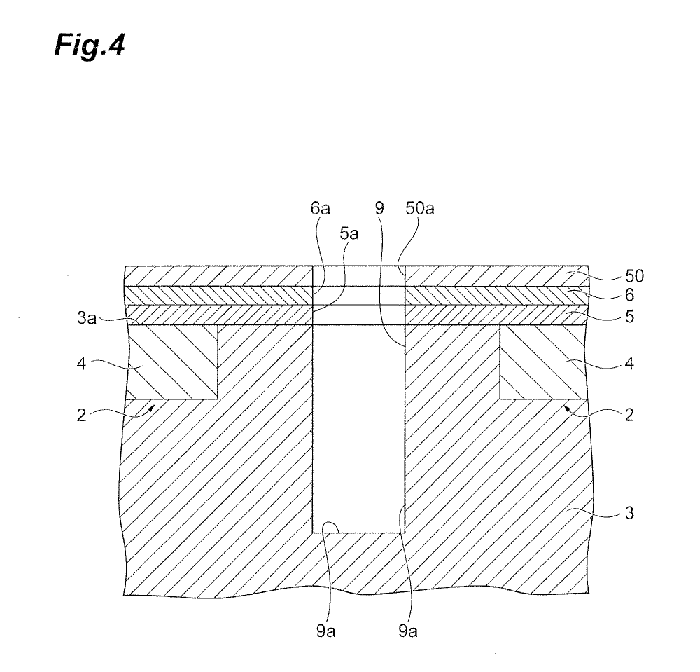

A method of manufacturing the optical semiconductor device 1 constituted as described above will be described. First, as illustrated in FIG. 3, the semiconductor substrate 3 having a plurality of photoelectric conversion parts 2 is prepared (first step). Subsequently, the insulating layers 5 and 6 are stacked, in turn, on the surface 3a of the semiconductor substrate 3. Subsequently, as illustrated in FIG. 4, a resist layer 50 is formed on the insulating layer 6, and a slit-shaped opening 50a corresponding to the opening of the trench 9 is formed in the resist layer 50 by photo-etching. Subsequently, slit-shaped openings 6a and 5a corresponding to the opening 50a are formed in the insulating layers 6 and 5 by plasma etching. Subsequently (after the first step), the trenches 9 are formed in the semiconductor substrate 3 by reactive ion etching (RIE) (second step). Thus, the trench 9 is formed in the semiconductor substrate 3 to separate the photoelectric conversion parts 2 from each other.

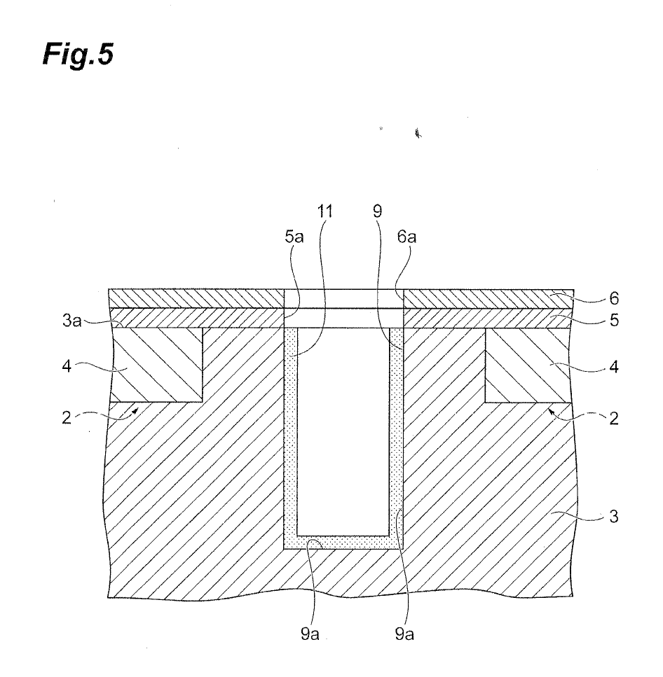

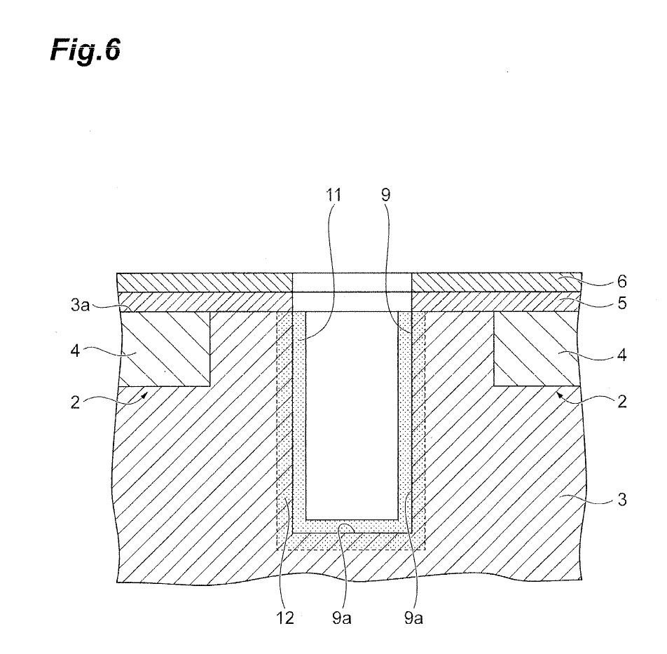

Subsequently (after the second step), the resist layer 50 is removed, and the boron layer 11 is formed on the inner surface 9a of the trench 9 by a vapor phase growth method, as illustrated in FIG. 5 (third step). The boron layer 11 is formed isotropically with a thickness of a few nm to several tens nm on the inner surface 9a of the trench 9 by a vapor phase growth method such as chemical vapor deposition (CVD) epitaxial growth or the like. Subsequently (after the third step), as illustrated in FIG. 6, the accumulation layer 12 is formed in the semiconductor substrate 3 along the inner surface 9a of the trench 9 by performing a thermal diffusion treatment on the boron layer 11 (fourth step).

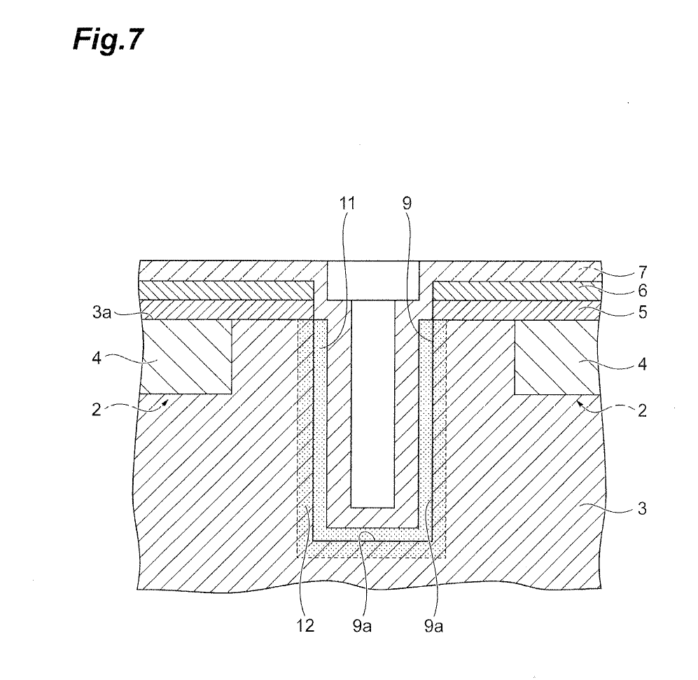

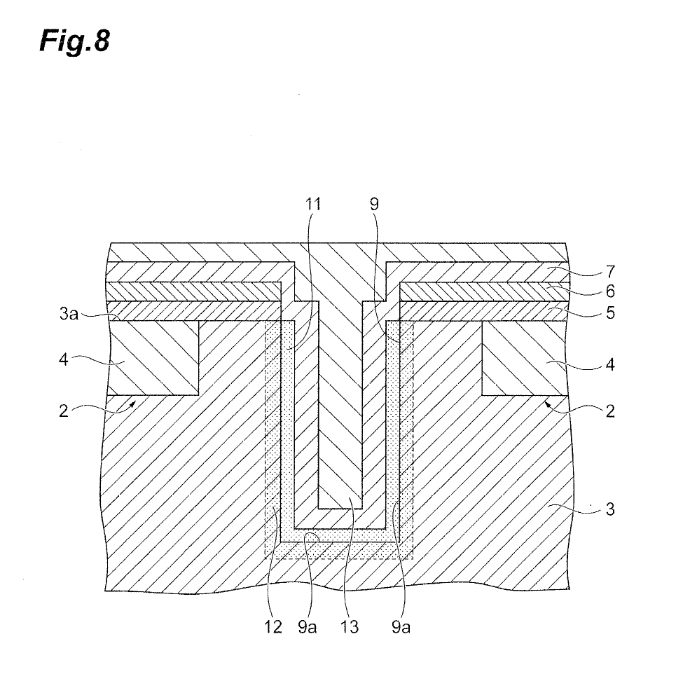

Subsequently, as illustrated in FIG. 7, the insulating layer 7 is stacked on the insulating layer 6 and the boron layer 11. Subsequently (after the fourth step), as illustrated in FIG. 8, the light shielding layer 13 is formed in the trenches 9 by filling the trench 9 with the light shielding material, for example, such as tungsten or polysilicon with the insulating layer 7 therebetween (fifth step). At this time, since a width of the opening of the trench 9 is limited by the insulating layer 7, the filling of the trench 9 with the light shielding material may be appropriately and uniformly carried out. Next, the light shielding layer 13 is flattened by etch back, and the insulating layer 8 is stacked on the insulating layer 7 to cover the light shielding layer 13 as illustrated in FIG. 2. Accordingly, the optical semiconductor device 1 is obtained.

Further, in the above-described method of manufacturing the optical semiconductor device 1, the boron layer 11 is formed on the inner surface 9a of the trench 9 by the vapor phase growth method. Thus, even in the case of the trench 9 which is deep and of which the opening has a narrow width, the boron layer 11 is formed isotropically on the inner surface 9a of the trench 9. Therefore, the accumulation layer 12 formed by the thermal diffusion of the boron layer 11 is uniformly formed in the semiconductor substrate 3 along the inner surface 9a of the trench 9. Also, since boron has a small molecular size, the thermal diffusion proceeds favorably in the boron layer 11. Accordingly, according to the method of manufacturing the optical semiconductor device 1, even in the case of the trench 9 of which the opening has a narrow and deep width, the accumulation layer 12 can be reliably formed to a deepest portion of the trench 9.

Further, in the above-described method of manufacturing the optical semiconductor device 1, the trench 9 is formed in the semiconductor substrate 3 by reactive ion etching. Therefore, it is possible to form the trench 9 which is deep and of which the width of the opening is narrow. In addition, since a defect can easily occur in the semiconductor substrate 3 along the inner surface 9a of the trench 9 when the reactive ion etching is performed, this manufacturing method is particularly effective because it is possible to reliably form the accumulation layer 12 to the deepest portion of the trench 9.

Further, in the above-described method of manufacturing the optical semiconductor device 1, the light shielding layer 13 is formed in the trench 9. Therefore, in the manufactured optical semiconductor device 1, it is possible to more reliably suppress the generation of the crosstalk between the photoelectric conversion parts 2 adjacent to each other.

Although one embodiment of the present disclosure has been described above, the present disclosure is not limited to the above-described embodiment. For example, the plurality of trenches 9 may be formed annularly to surround each of the photoelectric conversion parts 2 when seen in a direction perpendicular to the surface 3a of the semiconductor substrate 3. Further, the light shielding layer 13 may not be formed in the trench 9. Also in this case, the generation of the crosstalk between the photoelectric conversion parts 2 adjacent to each other can be suppressed by forming the trenches 9 in the semiconductor substrate 3 to separate the photoelectric conversion parts 2 from each other. In addition, when the optical semiconductor device 1 is a solid-state imaging device, it may be of a front surface incident type or a back surface incident type.

What is claimed is:

1. A method of manufacturing an optical semiconductor device, comprising:
preparing a semiconductor substrate having a plurality of photoelectric conversion parts,
forming a trench in the semiconductor substrate to separate the plurality of photoelectric conversion parts from each other,
forming a boron layer on an inner surface of the trench by a vapor phase growth method, and
forming an accumulation layer in the semiconductor substrate along the inner surface of the trench by performing a thermal diffusion treatment on the boron layer.

2. The method of manufacturing an optical semiconductor device according to claim 1,
wherein, in the forming of the trench, the trench is formed in the semiconductor substrate by reactive ion etching.

3. The method of manufacturing an optical semiconductor device according to claim 1, further comprising forming a light shielding layer in the trench after the forming of the accumulation layer.

4. The method of manufacturing an optical semiconductor device according to claim 2, further comprising forming a light shielding layer in the trench after the forming of the accumulation layer.
